(19) United States
(12) Patent Application Publication
(10) Pub. No.: US 2026/0299024 A1
(43) Pub. Date: Oct. 1, 2026

(54) CHARGE AND DISCHARGE PIN FOR SECONDARY BATTERY AND PROBE FOR CHARGE AND DISCHARGE TEST OF SECONDARY BATTERY INCLUDING CHARGE AND DISCHARGE PIN

(71) Applicant: SAMSUNG SDI CO., LTD., Yongin-si (KR)

(72) Inventors: Byeongryeol LEE, Yongin-si (KR); Soo-Mi EO, Yongin-si (KR); Won-Seok KIM, Yongin-si (KR); Dukju HAN, Yongin-si (KR)

(21) Appl. No.: 19/563,512

(22) Filed: Mar. 11, 2026

(30) Foreign Application Priority Data
Mar. 25, 2025 (KR) 10-2025-0037856

(51) Int. Cl. G01R 31/36; G01R 1/067; H01M 10/42; H01M 10/44

(52) U.S. Cl. CPC G01R 31/3644; G01R 1/06733; H01M 10/4285; H01M 10/44

(57) ABSTRACT

A charge and discharge pin for a secondary battery and a probe for a charge and discharge test of a secondary battery . The charge and discharge pin includes a head part including a front end surface and an outer peripheral surface, the front end surface configured to be in contact with a terminal of the secondary battery and the outer peripheral surface extending from the front end surface; a coupling part disposed on the head part and configured to be coupled to the terminal of the secondary battery; and an insulating member covering at least a portion of the outer peripheral surface of the head part.

### CROSS-REFERENCE TO RELATED APPLICATION

The present application claims priority to and the benefit of Korean Application No. 10-2025-0037856, filed on Mar. 25, 2025, in the Korean Intellectual Property Office, the entire disclosure of which is incorporated herein by reference.

### BACKGROUND

### Technical Field

The present disclosure relates to a charge and discharge pin for a secondary battery and a probe for a charge and discharge test of the secondary battery including the charge and discharge pin.

### Description of the Related Art

While primary batteries are not designed to be (re)charged, secondary (also known as rechargeable) batteries are batteries that are designed to be discharged and recharged. Among secondary batteries, low-capacity secondary batteries are widely used in portable, small electronic devices, such as smart phones, feature phones, notebook computers, digital cameras, and camcorders, while high-capacity secondary batteries are widely used as power sources for driving motors in hybrid vehicles and electric vehicles, as well as for storing power (e.g., home and/or utility scale power storage). A secondary battery generally includes an electrode assembly including a positive electrode and a negative electrode, a case accommodating both electrodes, and electrode terminals connected to the electrode assembly.

Meanwhile, in order to test performance or detect defects of a secondary battery, an electrical-characteristic measurement process is performed for every completed secondary battery and defective products that are not satisfactory are excluded. The electrical-characteristic measurement process includes a charge and discharge test.

In a battery cell (or secondary battery) using a stainless-steel case, residual flange portions that remain after welding and cutting processes may contact a charge and discharge pin during the charge and discharge test, thereby creating a risk of a short circuit. Particularly, to test a relatively high current, the cross-sectional size of the charge and discharge pin may increase and the thickness of the cell may decrease, increasing the possibility of a short circuit.

This Background section is for the general understanding of the background of the present disclosure, and therefore, it may contain information that does not constitute related (or prior) art.

### SUMMARY

Embodiments of the present disclosure provide a charge and discharge pin for a secondary battery and a probe for a charge and discharge test of the secondary battery.

Embodiments of the present disclosure provide a charge and discharge pin for a secondary battery including a head part including a front end surface that contacts a terminal of the secondary battery and an outer peripheral surface extending from the front end surface, a coupling part disposed on the head part and fixedly coupled to the terminal of the secondary battery, and an insulating member disposed so as to cover at least a portion of the outer peripheral surface of the head part.

Embodiments of the present disclosure provide a charge and discharge pin including a head part including a front end surface and an outer peripheral surface, the front end surface configured to be in contact with a terminal of the secondary battery and the outer peripheral surface extending from the front end surface; a coupling part disposed on the head part and configured to be coupled to the terminal of the secondary battery; and an insulating member covering at least a portion of the outer peripheral surface of the head part.

According to some embodiments of the present disclosure, the coupling part may include a protruding portion having a protruding shape, and the protruding portion may be configured to be fitted into a receiving part formed in the terminal of the secondary battery.

In some embodiments, the coupling part includes a protruding portion, and the protruding portion corresponds to a receiving part of the terminal of the secondary battery

According to some embodiments of the present disclosure, the coupling part may include a receiving part having a recessed shape, and a protruding portion formed in the terminal of the secondary battery may be configured to be fitted into the receiving part.

In some embodiments, the coupling part includes a receiving part, and the receiving part corresponds to a protruding portion of the terminal of the secondary battery.

According to some embodiments of the present disclosure, the coupling part may include a threaded portion having a protruding shape, and the threaded portion may be configured to be threadedly engaged with a threaded groove formed in the terminal of the secondary battery.

In some embodiments, the coupling part includes a threaded portion having a protruding geometry, and the threaded portion corresponds to a threaded groove of the terminal of the secondary battery.

According to some embodiments of the present disclosure, the coupling part may include a threaded groove having a recessed shape, and a threaded portion formed in the terminal of the secondary battery may be configured to be threadedly engaged with the threaded groove.

In some embodiments, the coupling part includes a threaded groove having a recessed geometry, and the threaded groove corresponds to a threaded portion of the terminal of the secondary battery.

According to some embodiments of the present disclosure, the coupling part may be disposed on the front end surface of the head part.

According to some embodiments of the present disclosure, the coupling part may be disposed in a through-hole formed in the front end surface of the head part.

According to some embodiments of the present disclosure, the insulating member may protrude beyond the front end surface while the front end surface of the head part is in contact with the terminal of the secondary battery and may be able to cover at least a portion of the terminal of the secondary battery.

In some embodiments, the insulating member is configured to protrude beyond the front end surface upon the front end surface of the head part being in contact with the terminal of the secondary battery, and the insulating member is configured to cover at least a portion of the terminal of the secondary battery.

According to some embodiments of the present disclosure, the insulating member may include a protruding portion that protrudes beyond the front end surface of the head part, and the protruding portion may be able to cover at least a portion of the terminal of the secondary battery while the head part is coupled to the terminal of the secondary battery.

In some embodiments, the insulating member includes a protruding portion protruding beyond the front end surface of the head part, and the protruding portion is configured to cover at least a portion of the terminal of the secondary battery upon the head part being coupled to the terminal of the secondary battery.

According to some embodiments of the present disclosure, a length of the protruding portion may be less than or equal to a length by which the terminal of the secondary battery protrudes from a case of the secondary battery.

According to some embodiments of the present disclosure, a thickness of the protruding portion may be less than or equal to a distance by which the terminal of the secondary battery is spaced apart from a flange part of a case of the secondary battery.

According to some embodiments of the present disclosure, the charge and discharge pin may further include an elastic member connected to the head part, the head part may move along an inner peripheral surface of the insulating member by an elastic force of the elastic member, and as the front end surface of the head part contacts the terminal of the secondary battery and the elastic member is compressed, the insulating member may protrude beyond the front end surface.

In some embodiments, the charge and discharge pin further includes an elastic member connected to the head part, wherein the head part is configured to move along an inner peripheral surface of the insulating member via the elastic member, and wherein when the front end surface of the head part is in contact with the terminal of the secondary battery, the elastic member is configured to be compressed, and the insulating member is configured to protrude beyond the front end surface

According to some embodiments of the present disclosure, the front end surface of the head part may correspond to a shape of the terminal of the secondary battery.

In some embodiments, a geometry of the front end surface of the head part corresponds to a geometry of the terminal of the secondary battery.

Embodiments of the present disclosure provide a probe for a charge and discharge test of a secondary battery including an outer plunger having a cylindrical shape and including an internal through-passage, an inner plunger that moves within the outer plunger, and a charge and discharge pin connected to the outer plunger and the inner plunger. The charge and discharge pin may include a head part connected to the outer plunger and including a front end surface that contacts a terminal of the secondary battery and an outer peripheral surface extending from the front end surface, a coupling part connected to the inner plunger and disposed on the head part and fixedly coupled to the terminal of the secondary battery, and an insulating member connected to the outer plunger and disposed so as to cover at least a portion of the outer peripheral surface of the head part.

Embodiments of the present disclosure provide a probe for a charge and discharge test of a secondary battery including: an outer plunger having a cylindrical geometry and including an internal through-passage; an inner plunger configured to move within the outer plunger; and a charge and discharge pin connected to the outer plunger and the inner plunger, wherein the charge and discharge pin includes: a head part connected to the outer plunger and including a front end surface and an outer peripheral surface, the front end surface configured to be in contact with a terminal of the secondary battery and the outer peripheral surface extending from the front end surface; a coupling part connected to the inner plunger, disposed on the head part, and configured to be coupled to the terminal of the secondary battery; and an insulating member connected to the outer plunger and covering at least a portion of the outer peripheral surface of the head part.

According to some embodiments of the present disclosure, the coupling part may include a protruding portion having a protruding shape, and the protruding portion may be configured to be fitted into a receiving part formed in the terminal of the secondary battery.

In some embodiments, the coupling part includs a protruding portion, and the protruding portion corresponds to a receiving part of the terminal of the secondary battery.

According to some embodiments of the present disclosure, the coupling part may include a receiving part having a recessed shape, and a protruding portion formed in the terminal of the secondary battery may be configured to be fitted into the receiving part.

In some embodiments, the coupling part includes a receiving part, and the receiving part corresponds to a protruding portion of the terminal of the secondary battery.

According to some embodiments of the present disclosure, the coupling part may be disposed in a through-hole formed in the front end surface of the head part.

According to some embodiments of the present disclosure, the insulating member may protrude beyond the front end surface while the front end surface of the head part is in contact with the terminal of the secondary battery and may be able to cover at least a portion of the terminal of the secondary battery.

In some embodiments, the insulating member is configured to protrude beyond the front end surface upon the front end surface of the head part being in contact with the terminal of the secondary battery, and the insulating member is configured to cover at least a portion of the terminal of the secondary battery.

According to some embodiments of the present disclosure, the insulating member may include a protruding portion that protrudes beyond the front end surface of the head part, and the protruding portion may be able to cover at least a portion of the terminal of the secondary battery while the head part is coupled to the terminal of the secondary battery.

In some embodiments, the insulating member includes a protruding portion protruding beyond the front end surface of the head part, and the protruding portion is configured to cover at least a portion of the terminal of the secondary battery upon the head part being coupled to the terminal of the secondary battery.

According to some embodiments of the present disclosure, the probe may further include an elastic member connected to the head part, the head part may move along an inner peripheral surface of the insulating member by an elastic force of the elastic member, and as the front end surface of the head part contacts the terminal of the secondary battery and the elastic member is compressed, the insulating member may protrude beyond the front end surface.

In some embodiments, the probe further includes an elastic member connected to the head part, wherein the head part is configured to move along an inner peripheral surface of the insulating member via the elastic member, and wherein when the front end surface of the head part is in contact with the terminal of the secondary battery, the elastic member is configured to be compressed, and the insulating member is configured to protrude beyond the front end surface.

According to some embodiments of the present disclosure, the head part of the charge and discharge pin for a secondary battery may be fixedly coupled to the terminal of the secondary battery, thereby preventing the charge and discharge pin from disengaging while it is connected to the terminal.

According to some embodiments of the present disclosure, while the head part of the charge and discharge pin for a secondary battery is in contact with the terminal of the secondary battery, the insulating member may be disposed so as to surround the terminal. Thus, the head part and the terminal may be more firmly connected and a risk of a short circuit caused by contact between the head part and a case may be minimized.

### BRIEF DESCRIPTION OF THE DRAWINGS

The drawings illustrate embodiments of the present disclosure and, together with the detailed description of the present disclosure, further describe aspects and features of the present disclosure. Accordingly, the present disclosure should not be construed as being limited to the drawings.

FIG. 1 is a longitudinal sectional view illustrating a probe for a charge and discharge test of a secondary battery according to embodiments of the present disclosure.

FIG. 2 is a perspective view illustrating a charge and discharge pin of the probe for a charge and discharge test of a secondary battery being coupled to the secondary battery according to embodiments of the present disclosure.

FIG. 3 is a cross-sectional view illustrating a secondary battery and a charge and discharge pin being coupled according to embodiments of the present disclosure.

FIG. 4 shows a coupling part according to embodiments of the present disclosure.

FIG. 5 shows a coupling part according to embodiments of the present disclosure.

FIG. 6 shows a coupling part according to embodiments of the present disclosure.

FIG. 7 is a cross-sectional view illustrating a secondary battery and a charge and discharge pin being coupled according to embodiments of the present disclosure.

FIG. 8 shows a coupling part according to embodiments of the present disclosure.

FIG. 9 shows a coupling part according to embodiments of the present disclosure.

FIG. 10 shows a protruding portion of an insulating member according to embodiments of the present disclosure.

FIG. 11 shows an insulating member being projected by an elastic member according to embodiments of the present disclosure.

### DETAILED DESCRIPTION

Hereinafter, embodiments of the present disclosure will be described in detail with reference to the accompanying drawings. The terms or words used in this specification and claims should not be construed as being limited to their usual or dictionary meanings and should be interpreted as having meanings and concepts consistent with the technical idea of the present disclosure based on the principle that an inventor may serve as his or her own lexicographer to appropriately define the concept of a term for best explaining the invention.

The embodiments described in this specification and the configurations shown in the drawings are only some of the embodiments of the present disclosure and do not represent all of the technical ideas, aspects, and features of the present disclosure. Accordingly, various equivalents and modifications capable of replacing or modifying the embodiments described herein at the time of filing this application will be apparent to a person skilled in the art.

It will be understood that when an element or layer is referred to as being “on,” “connected to,” or “coupled to” another element or layer, the element or layer may be directly on, connected to, or coupled to the other element or layer, or one or more intervening elements or layers may be present. When an element or layer is referred to as being “directly on,” “directly connected to,” or “directly coupled to” another element or layer, no intervening elements or layers are present. For example, when a first element is described as being “coupled” or “connected” to a second element, the first element may be directly coupled or connected to the second element or may be indirectly coupled or connected to the second element via one or more intervening elements.

To facilitate understanding of the disclosure, the attached drawings are not drawn to actual scale and the dimensions of some components may be exaggerated. Furthermore, the same reference numbers may be assigned to the same components in different embodiments. As used herein, the term “and/or” includes any and all combinations of one or more of the associated listed items. Further, the use of “may” when describing embodiments of the present disclosure relates to “one or more embodiments of the present disclosure.” Expressions such as “at least one of” and “any one of,” when preceding a list of elements, modify the entire list of elements and do not modify the individual elements of the list. When phrases such as “at least one of A, B and C,” “at least one of A, B or C,” “at least one selected from a group of A, B and C,” or “at least one selected from among A, B and C” are used to designate a list of elements A, B and C, the phrases may refer to any and all suitable combinations or subsets of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and are not terms of degree and are intended to account for inherent variations in measured or calculated values that would be recognized by a person of ordinary skill in the art.

It will be understood that although the terms first, second, third, and the like may be used herein to describe various elements, components, regions, layers, or sections, these elements, components, regions, layers, or sections should not be limited by these terms. These terms are used only to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe a positional relationship of one element or feature to another element or feature as illustrated in the figures. It will be understood that the spatially relative terms are intended to encompass different orientations of a device in use or operation in addition to the orientation depicted in the figures. For example, if the device in the figures is turned over, elements described as being “below” or “beneath” other elements or features would then be oriented “above” or “over” the other elements or features. Thus, the term “below” may encompass both above and below orientations. The device may be otherwise oriented (for example, rotated 90 degrees or at other orientations), and the spatially relative descriptors used herein should be interpreted accordingly.

The terminology used herein is for the purpose of describing embodiments of the present disclosure and is not intended to limit the present disclosure. As used herein, the singular forms “a” and “an” are intended to include the plural forms as well, unless the context clearly indicates otherwise. It will be further understood that the terms “includes,” “including,” “comprises,” and “comprising,” when used in this specification, specify the presence of stated features, integers, steps, operations, elements, and components but do not preclude the presence or addition of one or more other features, integers, steps, operations, elements, components, and groups thereof.

Also, any numerical range disclosed or recited herein is intended to include all sub-ranges of the same numerical precision subsumed within the recited range. For example, a range of “1.0 to 10.0” is intended to include all sub-ranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited herein is intended to include all higher numerical limitations subsumed therein. Accordingly, the applicant reserves the right to amend this specification, including the claims, to expressly recite any sub-range subsumed within the ranges expressly recited herein. All such ranges are intended to be inherently described in this specification such that amending to expressly recite any such sub-ranges would comply with the requirements of 35 U.S.C. § 112(a) and 35 U.S.C. § 132(a).

References to two compared elements or features as being “the same” may mean that the elements or features are “substantially the same.” Thus, the phrase “substantially the same” may include a deviation considered small in the art, for example, a deviation of 5 percent or less. In addition, when a certain parameter is referred to as being uniform in a given region, the parameter may be uniform in terms of an average.

Throughout the specification, unless otherwise stated, each element may be singular or plural.

Arranging an arbitrary element “above (or below)” or “on (under)” another element may mean that the arbitrary element is disposed in contact with an upper (or lower) surface of the other element, and another element may be interposed between the arbitrary element and the other element disposed on (or under) the other element.

In addition, it will be understood that when a component is referred to as being “linked,” “coupled,” or “connected” to another component, the components may be directly linked, coupled, or connected to each other, or another component may be interposed between the components.

Throughout the specification, when “A and/or B” is stated, unless otherwise stated, the phrase means A, B, or A and B. That is, “and/or” includes any and all combinations of a plurality of items enumerated. When “C to D” is stated, unless otherwise specified, the phrase means greater than or equal to C and less than or equal to D.

The terminology used herein is for the purpose of describing embodiments of the present disclosure and is not intended to be limiting of the present disclosure.

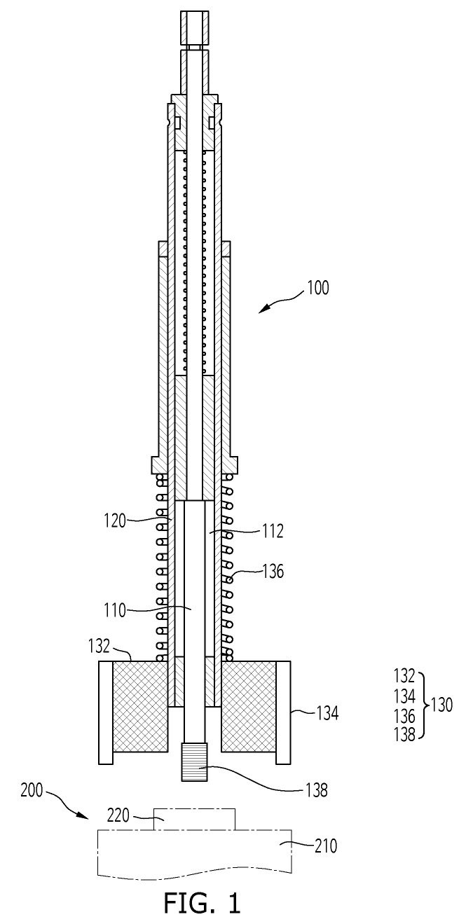

FIG. 1 is a longitudinal sectional view illustrating a probe for a charge and discharge test of a secondary battery. The probe 100 may include an outer plunger 120, an inner plunger 110, and a charge and discharge pin 130.

In an embodiment, the outer plunger 120 may have a cylindrical shape and may include an internal through-passage 112. The inner plunger 110 may move up and down along the internal through-passage 112 of the outer plunger 120. The inner plunger 110 may be electrically insulated from the outer plunger 120.

The charge and discharge pin 130 may be connected to end portions of the outer plunger 120 and the inner plunger 110. Alternatively, the charge and discharge pin 130 may be integrally formed with the outer plunger 120 and/or the inner plunger 110, and the charge and discharge pin 130 may refer to end regions of the outer plunger 120 and/or the inner plunger 110.

The charge and discharge pin 130 may include a head part 132 and an insulating member 134. The head part 132 and the insulating member 134 may be disposed at an end portion of the outer plunger 120. The insulating member 134 may cover at least a portion of the head part 132. For example, the head part 132 may be connected to an elastic member 136 to surround an outer circumference of the outer plunger 120. The insulating member 134 may be connected to the outer plunger 120 and separated from the head part 132, and the insulating member 134 may not be connected to the elastic member 136. In this manner, the head part 132 may move up and down along an inner peripheral surface of the insulating member 134 by an elastic force of the elastic member 136.

In an embodiment, the charge and discharge pin 130 may include a coupling part 138 connected to the inner plunger 110. The coupling part 138 may be disposed at an end portion of the inner plunger 110. The coupling part 138 may be disposed in a through-hole formed in the head part 132 and may protrude beyond the head part 132.

During a charge and discharge test of the secondary battery, the probe 100 may contact a terminal 220 of a secondary battery 200. Specifically, the head part 132 of the probe 100 may contact the terminal 220. When the head part 132 is separated while contacting the terminal 220 and contacts a case of the secondary battery 200, a short circuit may occur.

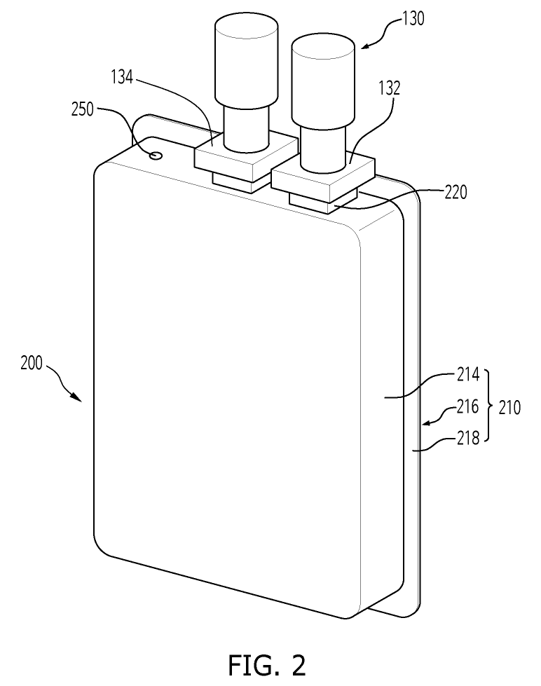

FIG. 2 is a perspective view illustrating a charge and discharge pin of the probe for a charge and discharge test of a secondary battery being coupled to the secondary battery. The charge and discharge pin 130 of the probe for a secondary battery charge and discharge test (for example, the probe 100 of FIG. 1) may be coupled to a terminal 220 of the secondary battery 200.

In an embodiment, the secondary battery 200 may include a case 210 and an electrode assembly disposed within the case 210. The electrode assembly may include a positive electrode, a negative electrode, and a separator interposed therebetween. The positive electrode and the negative electrode may be wounded while having the separator therebetween. However, the present disclosure is not limited thereto, and the electrode assembly may have a structure in which a plurality of sheets of positive electrodes and negative electrodes are alternately stacked with a separator interposed therebetween. The positive electrode and the negative electrode may include an active-material-coated region, which is a composite region in which an active material is applied on a current collector formed of a thin metal foil, and a noncoated region in which the active material is not coated.

In an embodiment, the secondary battery 200 may include a lithium battery cell or a sodium battery cell. However, the scope of the present disclosure is not limited thereto, and the secondary battery 200 may include any battery capable of repeatedly providing electricity through charge and discharge. For example, when the battery cell is a lithium battery cell, the battery cell may be used in a mobile phone, a power tool, or an electric bicycle. For example, the battery cell may be used in a hybrid vehicle, such as an electric vehicle (EV) or a plug-in hybrid electric vehicle (PHEV).

The case 210 forms an overall exterior of the secondary battery 200 and may include a metal such as stainless steel, aluminum, an aluminum alloy, or nickel-plated steel. In an embodiment, the case 210 may be manufactured in a geometry corresponding to the electrode assembly in order to accommodate the electrode assembly. The case 210 provides a space in which the electrode assembly is accommodated, and an insulating coating material may be applied with a predetermined thickness on an outer peripheral surface or an inner peripheral surface of the space.

The case 210 may include a terminal 220 that is electrically connected to a positive electrode and/or a negative electrode of the electrode assembly, a body case 214 that provides a space for accommodating the electrode assembly, and a cover case 216 that is coupled with the body case 214 to seal the case 210. The body case 214 may include a flange part 218 for coupling with the cover case 216.

In an embodiment, the positive electrode of the electrode assembly may be connected to a positive electrode terminal, and the negative electrode of the electrode assembly may be connected to the case 210. In this manner, the case 210 may function as an overall negative electrode.

The case 210 may be sealed by bonding or sealing the body case 214 and the cover case 216. For example, the body case 214 and the cover case 216 may be metal-bonded (for example, welded, brazed, or soldered). The body case 214 may include a flange part 218 for bonding with the cover case 216. In an embodiment, although the secondary battery case 210 may be manufactured using a rigid material so as to be metal-bonded, the present disclosure is not limited thereto.

The terminal 220 may include a positive electrode terminal electrically connected to the positive electrode and a negative electrode terminal electrically connected to the negative electrode. The terminal 220 may be formed integrally with the case 210. Additionally or alternatively, the terminal 220 may protrude through the case 210.

The terminal 220 may be formed on at least one surface of the case 210. For example, the terminal 220 may be formed on at least one surface of the body case 214 adjacent to the cover case 216. Although FIG. 2 illustrates two terminals 220 provided on one surface of the body case 210, the present disclosure is not limited thereto, and a position of the terminal 220 may be changed as needed.

In an embodiment, the case 210 may include an electrolyte injection port 250. For example, the electrolyte injection port 250 may be a through-hole formed in at least one surface of the case 210. The electrolyte injection port 250 may be formed to inject an electrolyte into the inside of the case 210 after the body case 214 and the cover case 216 are bonded and sealed. After the electrolyte is injected, the electrolyte injection port 250 may be sealed by a sealing member.

The secondary battery 200 illustrated in FIG. 2 is only an example, and the scope of the present disclosure is not limited thereto.

The charge and discharge pin 130 may include a head part 132 that contacts the terminal 220 of the secondary battery 200, a coupling part (not shown) disposed on the head part 132 and fixedly coupled to the terminal 220, and an insulating member 134 disposed so as to cover at least a portion of the head part 132.

In an embodiment, the head part 132 may include the front end surface that contacts the terminal 220 of the secondary battery 200 and the outer peripheral surface extending from the front end surface. In this manner, the coupling part may be disposed toward the front end surface of the head part 132. For example, the coupling part may be disposed on the front end surface of the head part 132. For example, the coupling part may be disposed in a through-hole formed on the front end surface of the head part 132.

In an embodiment, a counterpart coupling part having a structure corresponding to the coupling part of the head part 132 may be formed in the terminal 220 of the secondary battery 200. For example, the coupling part of the head part 132 may include a protruding portion having a protruding shape, and the counterpart coupling part of the terminal 220 may include a receiving part for receiving the protruding portion. For example, the coupling part of the head part 132 may include a receiving part having a recessed shape, and the counterpart coupling part of the terminal 220 may include a protruding portion received in the recessed receiving part.

In an embodiment, the insulating member 134 may cover at least a portion of the head part 132. Accordingly, the head part 132 may be electrically insulated from the case 210. For example, by utilizing the insulating member 134 to cover the head part 132, interference, both electrical and/or physical, between the flange part 218 of the case 210 and the head part 132 may be prevented. Additionally, while the head part 132 and the terminal 220 are coupled, the insulating member 134 may cover at least a portion of the terminal 220.

The insulating member 134 may include an insulating material. For example, the insulating member 134 may include a polymer including ethylene-propylene-diene-monomer rubber (EPDM), polypropylene (PP), polyimide (PI), polyethylene terephthalate (PET), polycarbonate (PC), or a combination thereof. For example, the insulating member 134 may include a ceramic material including epoxy resin, alumina (Al₂O₃), zirconia (ZrO₂), aramid fiber, Nomex, or a combination thereof. However, a material of the insulating member 134 is not limited to the materials listed and may include various materials that have plasticity and insulation properties selected by a person skilled in the art.

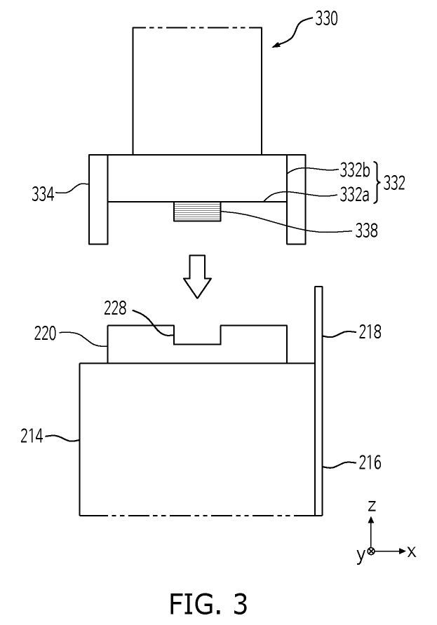

FIG. 3 is a cross-sectional view illustrating a secondary battery and a charge and discharge pin being coupled. The charge and discharge pin 330 may include a head part 332 that contacts the terminal 220 of the secondary battery, a coupling part 338 disposed on the head part 332 and fixedly coupled to the terminal 220, and an insulating member 334 disposed so as to cover at least a portion of the head part 332.

In an embodiment, the terminal 220 of the secondary battery may protrude from the case of the secondary battery. For example, the case of the secondary battery may include a body case 214 having one surface open and a cover case 216 coupled with the body case 214 to seal the open surface of the body case 214. The terminal 220 may protrude from one surface of the body case 214. For bonding the body case 214 and the cover case 216, the body case 214 and/or the cover case 216 may include a flange part 218 that protrudes along an edge region of the cover case 216. The flange part 218 may protrude in a direction (for example, a Z-axis direction) in which the terminal 220 protrudes.

In an embodiment, the terminal 220 of the secondary battery may be connected to the positive electrode of the electrode assembly and may function as a positive electrode terminal. The case of the secondary battery may be connected to the negative electrode of the electrode assembly and may function as a negative electrode terminal.

In an embodiment, the head part 332 may include a front end surface 332a that contacts the terminal 220 and an outer peripheral surface 332b extending from the front end surface 332a. For example, the head part 332 may be substantially rectangular parallelepiped. In this manner, the front end surface 332a may refer to one surface of the head part 332 that faces the terminal 220. The outer peripheral surface 332b may refer to a side surface of the head part 332 adjacent to the front end surface 332a.

In an embodiment, the head part 332 may be fixedly coupled while contacting the terminal 220. Specifically, the coupling part 338 of the head part 332 and a counterpart coupling part 228 of the terminal 220 may be coupled so that the head part 332 is fixed while contacting the terminal 220.

In an embodiment, the coupling part 338 may protrude from the front end surface 332a of the head part 332.

In an embodiment, the insulating member 334 may cover at least a portion of the head part 332. Consequently, the head part 332 may be electrically insulated from the case. Specifically, by utilizing the insulating member 334 to cover the head part 332, interference between the head part 332 and the flange part 218 of the case may be prevented. Additionally, while the head part 332 and the terminal 220 are coupled, the insulating member 334 may protrude beyond the front end surface 332a of the head part 332 and may surround a peripheral side of the terminal 220.

By coupling the coupling part 338 of the head part 332 with the counterpart coupling part 228 of the terminal 220 and by utilizing the insulating member 334 to surround the terminal 220 while the head part 332 contacts the terminal 220, the head part 332 and the terminal 220 may be firmly coupled. Accordingly, disengagement of the charge and discharge pin 330 from the terminal 220 may be prevented while the charge and discharge pin 330 is connected to the terminal 220. In addition, when the case of the secondary battery functions as a negative electrode terminal, a risk of a short circuit caused by contact between the head part 332 and the case may be minimized.

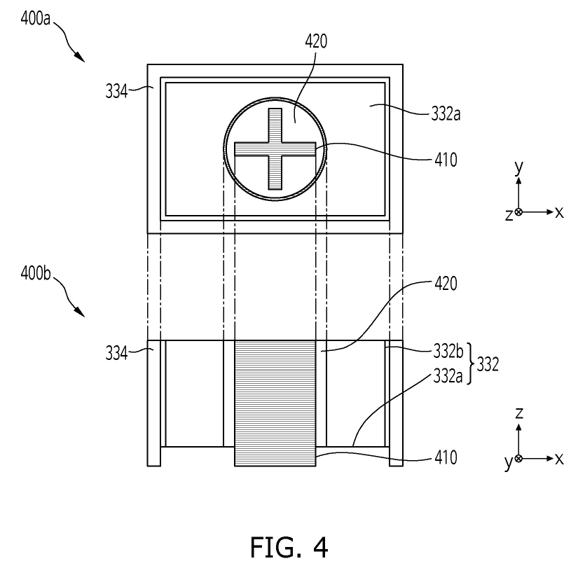

FIGS. 4 to 6 show a coupling part.

Referring to FIG. 4, a bottom plan view 400a illustrates the head part 332 of the charge and discharge pin (for example, the charge and discharge pin 330 of FIG. 3) viewed from a lower direction, and a longitudinal sectional view 400b is taken through the head part 332 of the charge and discharge pin.

In an embodiment, a shape of the front end surface 332a may correspond to a shape of the terminal of the secondary battery with which the front end surface 332a contacts. Referring to the bottom plan view 400a, the front end surface 332a of the head part 332 may be substantially rectangular. However, the present disclosure is not limited thereto, and the geometry may be appropriately changed to circle, ellipse, or a polygon according to the geometry of the terminal.

In an embodiment, a coupling part 410 may protrude from the front end surface 332a of the head part 332. For example, the coupling part 410 may include a protruding portion protruding from the front end surface 332a. In FIG. 4, a cross-sectional geometry of the coupling part 410 is illustrated as a cross, but the present disclosure is not limited thereto, and a cross-sectional geometry of the coupling part 410 may take various forms such as a circle, line, or polygon.

Although not illustrated, a terminal coupled with the head part 332 may include a counterpart coupling part having a shape corresponding to the coupling part 410. For example, the counterpart coupling part of the terminal may include a receiving part for receiving the protruding portion protruding from the front end surface 332a. In this manner, a cross-sectional shape of the receiving part may correspond to a cross-sectional shape of the coupling part 410. The protruding portion of the head part 332 may be fitted into the receiving part formed in the terminal of the secondary battery, thereby limiting movement of the head part 332 in a horizontal direction (for example, an X-axis direction or a Y-axis direction).

In an embodiment, the coupling part 410 may protrude through a through-hole 420 of the front end surface 332a. For example, the through-hole 420 may be formed in the front end surface 332a of the head part 332, and the coupling part 410 may be disposed in the through-hole 420. In this manner, the coupling part 410 may move up and down (for example, in a Z-axis direction) through the through-hole 420; however, the present disclosure is not limited thereto.

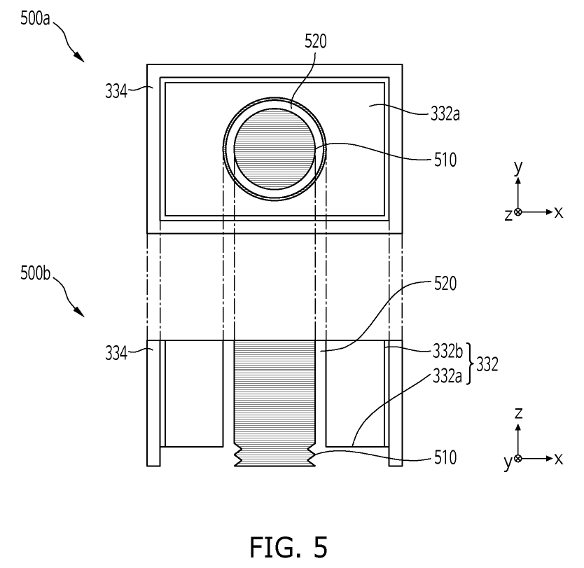

Referring to FIG. 5, a bottom plan view 500a illustrates the head part 332 of the charge and discharge pin (for example, the charge and discharge pin 330 of FIG. 3) viewed from a lower direction, and a longitudinal sectional view 500b is taken through the head part 332 of the charge and discharge pin. In an embodiment, a coupling part 510 may protrude from the front end surface 332a of the head part 332. For example, the coupling part 510 may include a threaded portion protruding from the front end surface 332a. A terminal coupled with the head part 332 may include a counterpart coupling part having a shape corresponding to the coupling part 510. Specifically, the counterpart coupling part of the terminal may include a threaded groove for coupling with the threaded portion of the head part 332. The threaded portion of the head part 332 may be threadedly engaged with the threaded groove formed in the terminal of the secondary battery, thereby limiting movement of the head part 332 in a horizontal direction (for example, an X-axis direction or a Y-axis direction).

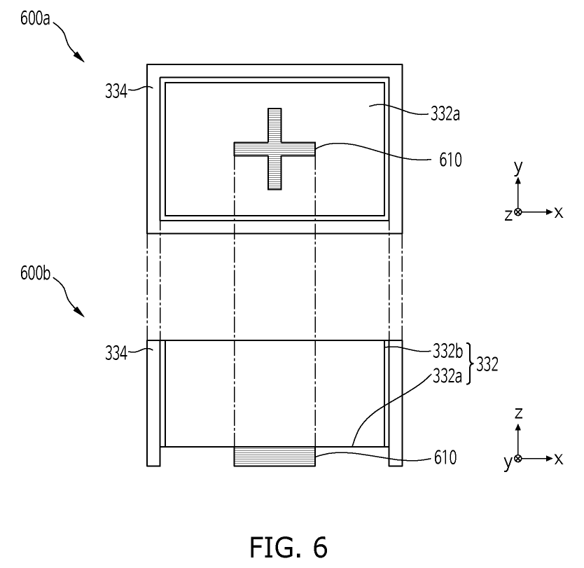

Referring to FIG. 6, a bottom plan view 600a illustrates the head part 332 of the charge and discharge pin (for example, the charge and discharge pin 330 of FIG. 3) viewed from a lower direction, and a longitudinal sectional view 600b is taken through the head part 332 of the charge and discharge pin. In an embodiment, a coupling part 610 may protrude from the front end surface 332aof the head part 332. In this manner, the coupling part 610 may be disposed on the front end surface 332a of the head part 332.

In an embodiment, the coupling part 610 may include a protruding portion protruding from the front end surface 332a. A counterpart coupling part of a terminal coupled with the coupling part 610 may include a receiving part for receiving the protruding portion. The receiving part may be formed in a shape corresponding to the protruding portion. The coupling part 610 of the head part 332 may be fitted into the counterpart coupling part of the terminal, thereby limiting movement of the head part 332 in a horizontal direction (for example, an X-axis direction or a Y-axis direction).

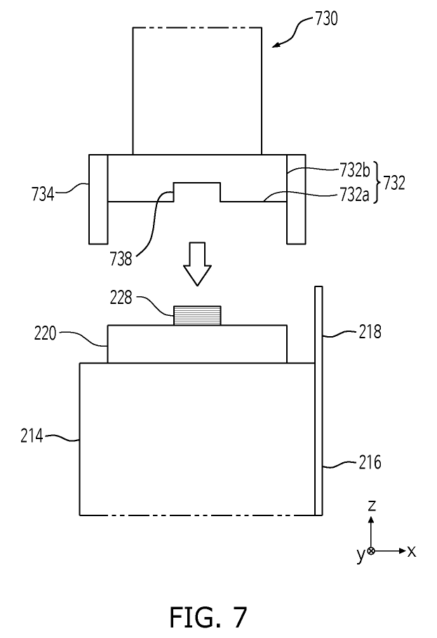

FIG. 7 is a cross-sectional view illustrating a secondary battery and a charge and discharge pin being coupled. The charge and discharge pin 730 may include a head part 732 that contacts the terminal 220 of the secondary battery, a coupling part 738 disposed on the head part 732 and fixedly coupled to the terminal 220, and an insulating member 734 to cover at least a portion of the head part 732.

In an embodiment, the head part 732 may include a front end surface 732a that contacts the terminal 220 and an outer peripheral surface 732b extending from the front end surface 732a. The head part 732 may be fixed while contacting the terminal 220. Specifically, the coupling part 738 of the head part 732 and a counterpart coupling part 228 of the terminal 220 may be coupled so that the head part 732 is fixed while contacting the terminal 220.

In an embodiment, the coupling part 738 may be recessed relative to the front end surface 732a of the head part 732.

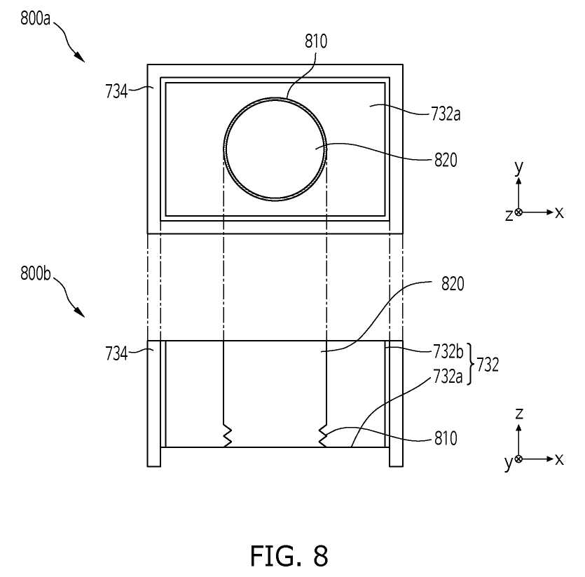

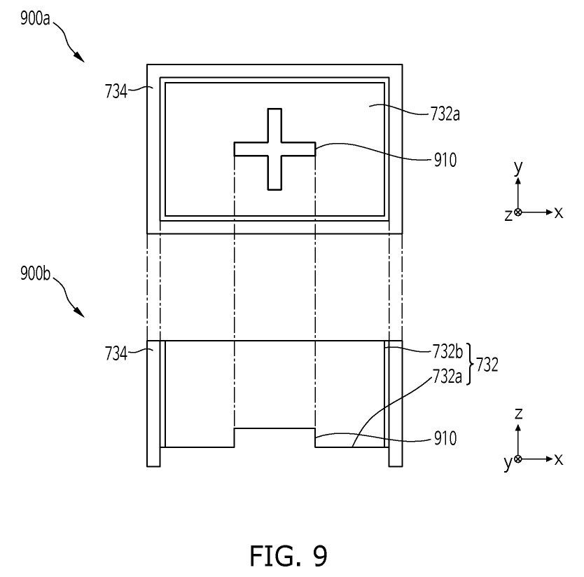

FIGS. 8 and 9 show a coupling part.

Referring to FIG. 8, a bottom plan view 800a illustrates the head part 732 of the charge and discharge pin (for example, the charge and discharge pin 730 of FIG. 7) viewed from a lower direction, and a longitudinal sectional view 800b is taken through the head part 732 of the charge and discharge pin.

In an embodiment, a coupling part 810 may be formed inside the head part 732. For example, a through-hole 820 may be formed in the front end surface 732a of the head part 732, and the coupling part 810 may be formed along an inner surface of the through-hole 820. In FIG. 8, the through-hole 820 is illustrated as being formed along an entire height of the head part 732 (for example, a Z-axis direction height of the head part 732). However, the present disclosure is not limited thereto, and the through-hole 820 may be formed to a predetermined height of the head part 732.

In an embodiment, the coupling part 810 may include a threaded groove formed along an inner surface of the through-hole 820. A terminal coupled with the head part 732 may include a counterpart coupling part having a shape corresponding to the coupling part 810. Specifically, the counterpart coupling part of the terminal may include a threaded portion protruding from the terminal to be coupled with the threaded groove of the head part 732. Accordingly, a threaded portion formed in the terminal of the secondary battery may be threadedly engaged with the threaded groove formed in the head part 732.

Referring to FIG. 9, a bottom plan view 900a illustrates the head part 732 of the charge and discharge pin (for example, the charge and discharge pin 730 of FIG. 7) viewed from a lower direction, and a longitudinal sectional view 900b is taken through the head part 732 of the charge and discharge pin.

In an embodiment, a coupling part 910 may be offset from the front end surface 732a of the head part 732. For example, the coupling part 910 may include a recessed receiving part offset relative to the front end surface 732a. A terminal coupled with the head part 732 may include a counterpart coupling part having a geometry corresponding to the coupling part 910. Specifically, the counterpart coupling part of the terminal may include a protruding portion to be coupled with the receiving part of the head part 732. Accordingly, a protruding portion formed in the terminal of the secondary battery may be fitted into the receiving part formed in the coupling part 910 of the head part 732.

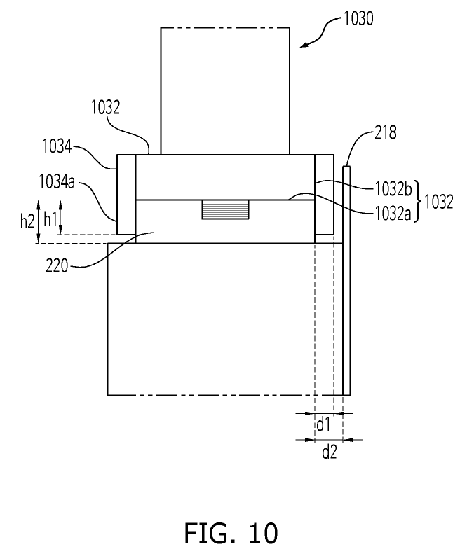

FIG. 10 shows a protruding portion 1034a of an insulating member 1034. The insulating member 1034 may cover at least a portion of a head part 1032 of a charge and discharge pin 1030. By utilizing the insulating member 1034 to cover the head part 1032, interference between a flange part 218 of a case and the head part 1032 may be prevented.

In an embodiment, the insulating member 1034 may cover at least a portion of the terminal 220 while the head part 1032 and the terminal 220 are coupled. For example, the insulating member 1034 may include a protruding portion 1034a protruding beyond a front end surface 1032a of the head part 1032. Accordingly, when the head part 1032 and the terminal 220 are coupled, the protruding portion 1034a of the insulating member 1034 may surround the terminal 220.

In an embodiment, a length h1 of the protruding portion 1034a may be less than or equal to a length h2 by which the terminal 220 protrudes from the case of the secondary battery. Therefore, contact between the front end surface 1032a of the head part 1032 and the terminal 220 may not be hindered by the protruding portion 1034a. In addition, a thickness d1 of the protruding portion 1034a may be less than or equal to a distance d2 by which the terminal 220 of the secondary battery is spaced apart from the flange part 218 of the case of the secondary battery. Accordingly, the protruding portion 1034a may be smoothly inserted into a space in which the terminal 220 of the secondary battery and the flange part 218 of the case of the secondary battery are spaced apart.

By utilizing the protruding portion 1034a of the insulating member 1034 to surround the terminal 220, separation of the head part 1032 while the head part 1032 is coupled to the terminal 220 may be prevented. Even if the head part 1032 is disengaged from the terminal 220, the head part 1032 may not contact the case of the secondary battery by the protruding portion 1034a of the insulating member 1034.

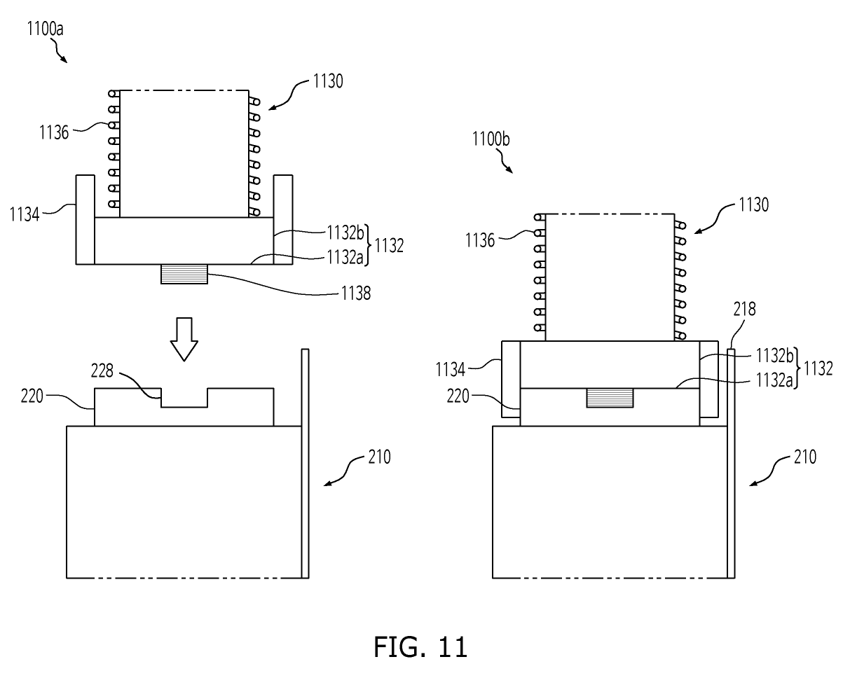

FIG. 11 shows an insulating member being projected by an elastic member . In an embodiment, a charge and discharge pin 1130 may include the elastic member 1136 connected to a head part 1132. The head part 1132 may move up and down along an inner peripheral surface of the insulating member 1134 by an elastic force of the elastic member 1136.

View 1100a illustrates the head part 1132 of the charge and discharge pin 1130 prior to being coupled to the terminal 220 of a secondary battery. The insulating member 1134 may not protrude beyond a front end surface 1132a of the head part 1132.

View 1100b illustrates the head part 1132 of the charge and discharge pin 1130 being coupled to the terminal 220 of a secondary battery. Specifically, the charge and discharge pin 1130 may move downward in a direction facing the terminal 220. Accordingly, as the front end surface 1132a of the head part 1132 contacts the terminal 220, the elastic member 1136 connected to the head part 1132 may be compressed.

In this manner, the head part 1132 may move upward along the inner peripheral surface of the insulating member 1134. Specifically, the head part 1132 may move upward relative to the insulating member 1134. As the head part 1132 moves, the insulating member 1134 may protrude beyond the front end surface 1132a of the head part 1132, thereby surrounding the terminal 220.

Although the present disclosure has been described above with respect to embodiments thereof, the present disclosure is not limited thereto. Various modifications and variations can be made by a person skilled in the art without departing from the spirit of the present disclosure.

### DESCRIPTION OF SOME REFERENCE SYMBOLS

100: probe

110: inner plunger

112: through-passage

120: outer plunger

130: charge and discharge pin

132: head part

134: insulating member

136: elastic member

138: coupling part

200: secondary battery

210: case

220: electrode terminal

What is claimed is:

1. A charge and discharge pin for a secondary battery, comprising:
a head part including a front end surface and an outer peripheral surface, the front end surface configured to be in contact with a terminal of the secondary battery and the outer peripheral surface extending from the front end surface;
a coupling part disposed on the head part and configured to be coupled to the terminal of the secondary battery; and
an insulating member covering at least a portion of the outer peripheral surface of the head part.

2. The charge and discharge pin as claimed in claim 1, wherein the coupling part comprises a protruding portion, and
wherein the protruding portion corresponds to a receiving part of the terminal of the secondary battery.

3. The charge and discharge pin as claimed in claim 1, wherein the coupling part comprises a receiving part, and
wherein the receiving part corresponds to a protruding portion of the terminal of the secondary battery.

4. The charge and discharge pin as claimed in claim 1, wherein the coupling part comprises a threaded portion having a protruding geometry, and
wherein the threaded portion corresponds to a threaded groove of the terminal of the secondary battery.

5. The charge and discharge pin as claimed in claim 1, wherein the coupling part comprises a threaded groove having a recessed geometry, and
wherein the threaded groove corresponds to a threaded portion of the terminal of the secondary battery.

6. The charge and discharge pin as claimed in claim 1, wherein the coupling part is disposed on the front end surface of the head part.

7. The charge and discharge pin as claimed in claim 1, wherein the coupling part is disposed in a through-hole formed in the front end surface of the head part.

8. The charge and discharge pin as claimed in claim 1, wherein the insulating member is configured to protrude beyond the front end surface upon the front end surface of the head part being in contact with the terminal of the secondary battery, and
wherein the insulating member is configured to cover at least a portion of the terminal of the secondary battery.

9. The charge and discharge pin as claimed in claim 1, wherein the insulating member includes a protruding portion protruding beyond the front end surface of the head part, and
wherein the protruding portion is configured to cover at least a portion of the terminal of the secondary battery upon the head part being coupled to the terminal of the secondary battery.

10. The charge and discharge pin as claimed in claim 9, wherein a length of the protruding portion is less than or equal to a length by which the terminal of the secondary battery protrudes from a case of the secondary battery.

11. The charge and discharge pin as claimed in claim 9, wherein a thickness of the protruding portion is less than or equal to a distance by which the terminal of the secondary battery is spaced apart from a flange part of a case of the secondary battery.

12. The charge and discharge pin as claimed in claim 1, further comprising an elastic member connected to the head part,
wherein the head part is configured to move along an inner peripheral surface of the insulating member via the elastic member, and
wherein when the front end surface of the head part is in contact with the terminal of the secondary battery, the elastic member is configured to be compressed, and the insulating member is configured to protrude beyond the front end surface.

13. The charge and discharge pin as claimed in claim 1, wherein a geometry of the front end surface of the head part corresponds to a geometry of the terminal of the secondary battery.

14. A probe for a charge and discharge test of a secondary battery, comprising:
an outer plunger having a cylindrical geometry and including an internal through-passage;
an inner plunger configured to move within the outer plunger; and
a charge and discharge pin connected to the outer plunger and the inner plunger,
wherein the charge and discharge pin comprises:
a head part connected to the outer plunger and including a front end surface and an outer peripheral surface, the front end surface configured to be in contact with a terminal of the secondary battery and the outer peripheral surface extending from the front end surface;
a coupling part connected to the inner plunger, disposed on the head part, and configured to be coupled to the terminal of the secondary battery; and
an insulating member connected to the outer plunger and covering at least a portion of the outer peripheral surface of the head part.

15. The probe as claimed in claim 14, wherein the coupling part comprises a protruding portion, and
wherein the protruding portion corresponds to a receiving part of the terminal of the secondary battery.

16. The probe as claimed in claim 14, wherein the coupling part comprises a receiving part, and
wherein the receiving part corresponds to a protruding portion of the terminal of the secondary battery.

17. The probe as claimed in claim 14, wherein the coupling part is disposed in a through-hole formed in the front end surface of the head part.

18. The probe as claimed in claim 14, wherein the insulating member is configured to protrude beyond the front end surface upon the front end surface of the head part being in contact with the terminal of the secondary battery, and
wherein the insulating member is configured to cover at least a portion of the terminal of the secondary battery.

19. The probe as claimed in claim 14, wherein the insulating member includes a protruding portion protruding beyond the front end surface of the head part, and
wherein the protruding portion is configured to cover at least a portion of the terminal of the secondary battery upon the head part being coupled to the terminal of the secondary battery.

20. The probe as claimed in claim 14, further comprising an elastic member connected to the head part,
wherein the head part is configured to move along an inner peripheral surface of the insulating member via the elastic member, and
wherein when the front end surface of the head part is in contact with the terminal of the secondary battery, the elastic member is configured to be compressed, and the insulating member is configured to protrude beyond the front end surface.
